(19) United States
(12) Patent Application Publication
(10) Pub. No.: US 2025/0233066 A1
(43) Pub. Date: Jul. 17, 2025

(54) THREE DIMENSIONAL CHIP AND PACKAGE INTEGRATION WITH BACKSIDE METALLIZATION

(71) Applicant: NVIDIA Corp., Santa Clara, CA (US)

(72) Inventors: Mahmut Ersin Sinangil, Los Altos, CA (US); Sudhir Shrikantha Kudva, Dublin, CA (US); Tezaswi Raja, San Jose, CA (US); Brian Matthew Zimmer, Sunnyvale, CA (US); Brucek Kurdo Khailany, Rollingwood, TX (US); Carl Thomas Gray, Apex, NC (US); John Wilson, Wake Forest, NC (US)

(73) Assignee: NVIDIA Corp., Santa Clara, CA (US)

(21) Appl. No.: 18/415,090

(22) Filed: Jan. 17, 2024

(51) Int. Cl. H01L 23/528; H01L 23/48; H01L 25/18

(52) U.S. Cl. CPC H01L 23/528; H01L 23/481; H01L 25/18

(57) ABSTRACT

Three-dimensional integrated circuit stack configurations include a bottom die configured with bottom die back side metallization and bottom die front side metallization, and a top die configured with metal layers adjacent to the bottom die front side metallization. The bottom die is configured to pass power from the bottom die back side metallization to the metal layers of the top die by way of back side pass-through vias formed in dummy cells interspersed among active logic cells of the bottom die.

### BACKGROUND

Three-dimensional (3D) chip and package stacking enables the integration of more circuitry and hence more functionality into an available area footprint. 3D stacking may also enhance the performance and energy efficiency of electronic devices. For most cases, power and signals are input from one side of the 3D stack necessitating at least one of the chips to provide a power feed-through path to the other chip(s). These feed-throughs often take the form of through-silicon via (TSVs) and come at the expense of silicon area because of the keep-out regions these TSVs utilize in the circuit layout and the pitch distance between them to mitigate electromagnetic interference.

Consequently, in conventional 3D stacking layouts, the TSVs (especially for power distribution) tend to clustered on the die rather than being distributed more evenly over the die. This imposes further limitations on layout and signal and power fan-out from TSV regions to the rest of the circuitry.

Back side metallization is a process technology that enables metallization of both front side and back side of transistors. In integrated circuit fabrication, multiple dies are formed on a semiconductor wafer (e.g., a silicon wafer). Prior to separation of the dies from the wafer, a layer of metal may be deposited on the back side of the wafer. The back side of the wafer is opposite the side of the wafer on which active components such as transistors are formed. Back side metallization provides an electrically conductive contact and/or a heat conductive contact for the dies. Back side metallization is often employed in power devices to provide improved heat dissipation.

### BRIEF DESCRIPTION OF THE SEVERAL VIEWS OF THE DRAWINGS

FIG. 1 depicts an example of conventional 3D chip stacking.

FIG. 2 depicts a cross section view of a die with back side metallization.

FIG. 3 depicts a cross-sectional view of through-silicon vias.

FIG. 4 depicts an exemplary distributed placement of backside vias. The view direction is orthogonal to the plane of the active logic substrate.

FIG. 5A and FIG. 5B depict stacked configurations wherein at least one chip utilizes back side metallization.

FIG. 6 depicts an example distribution of backside vias across power gating standard cells.

FIG. 7 depicts an embodiment of a three-die stacked configuration wherein the top and bottom die are homogeneous, and a capacitor die is included to improve power delivery.

FIG. 8A depicts an example of heat conduction in a conventional chip.

FIG. 8B depicts an example of heat conduction in a chip utilizing back side metallization.

FIG. 9A and FIG. 9B depict an example configuration of dedicated grids and thermally-optimized fill scripts to improve heat conduction in chips utilizing back side metallization.

### DETAILED DESCRIPTION

Backside metal may be utilized for power and I/O paths between chips, and front side metal may be utilized for local connections between the active components inside particular chips. The connection from back side to front side may be implemented with backside vias that are smaller (in some cases, orders of magnitude smaller) than conventional TSVs. Consequently, back side metallization mechanisms described herein enable replacement of single, larger TSVs each with multiple smaller backside vias. A back side via is formed during manufacturing of the back side of the silicon substrate (opposite the front side, where the active logic is fabricated).

TSVs are distinguished from backside vias by the process steps utilized for their manufacture. TSVs are lithographically formed by crating a void in the wafer (e.g., with a laser drill) and filling the void with metal. Backside vias are formed in a thin layer of material (along with transistors) formed on the wafer (the wafer material is then removed, leaving only the thin layer). Consequently, backside vias penetrate a shorter distance through material (e.g., two orders of magnitude shorter) compared to conventional TSVs.

Disclosed herein are mechanisms to utilize back side metallization with chips and packages configured in 3D stacked configurations. Power management mechanisms are also described that benefit from the higher density and less invasive pass through that backside vias provide. Power grid embodiments are described configured to address heat transfer issues that may arise in power nets implemented with back side metallization.

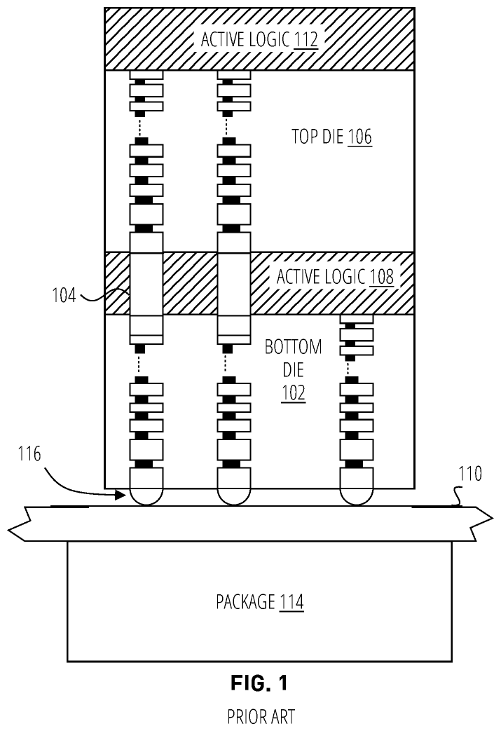

FIG. 1 depicts a conventional 3D stacked configuration of two chips. Both die are depicted in a face down orientation (metal layers closer to the power and IO peripheral interface than the active logic of the chip) but generally either or both die may be configured in a face up orientation as well. The bottom die 102 is configured face down and comprises through-silicon vias 104 to provide power and IO signals to the top die 106 (also placed face-down). Herein, “top die” and “bottom die” are terms that refer to the relative positions of the die in the stack—the bottom die is configured closer to the power and IO periphery of the stack than the top die, and thus power and IO signals pass through the bottom die to reach the top die.

The bottom die 102 comprises active logic 108. The through-silicon vias 104 traverse the active logic 108 of the bottom die 102 to provide power to and to exchange IO signals with the active logic 112 of the top die 106. The through-silicon vias 104 are openings formed in the silicon medium, typically filled with metal to form a low resistance electrical path.

Power to both chips is provided through an interposer 110 from a circuit package 114 via solder terminals 116. The solder terminals 116 also function to provide IO signals between the package 114 and the chips.

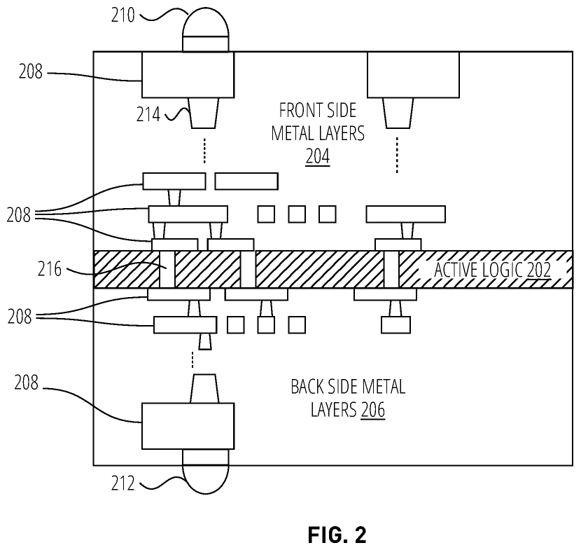

FIG. 2 depicts a cross-section view of active logic 202, e.g., an integrated circuit chip, with back side metallization. The transistors utilized in the active logic 202 utilize both of front side metal layers 204 and back side metal layers 206. The metal layers 208 on both sides may be utilized for local connections in the active logic 202. In many process technologies and/or integrated circuits, but not all, the metal layers 208 tend to be thicker and spaced further apart the closer they are to the chip pinout periphery.

Power and IO signals pass from solder pins 210, 212 on the chip's pinout periphery through inter-metal layer vias 214 to the active logic 202. Connections between the front side metal layers 204 and the back side metal layers 206 may be implemented with backside vias 216 that enable tight pitches (comparable to minimum poly pitches) so that connections to individual transistors may be achieved.

For structural integrity of the die comprising the active logic 202, additional supporting structure (not depicted) may be added during manufacturing of the back side metallization.

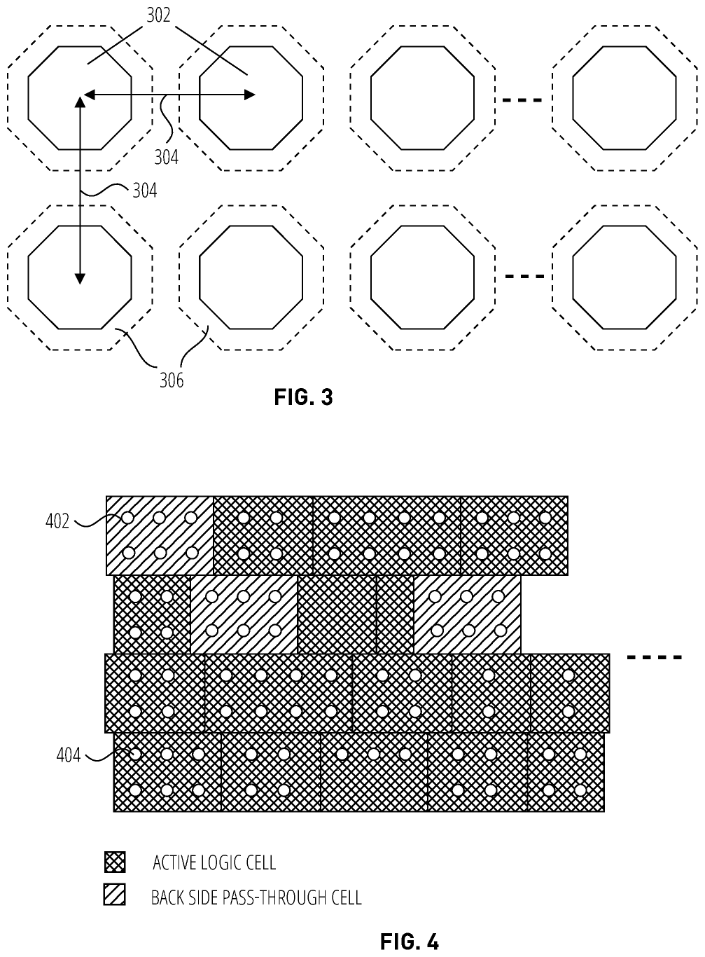

FIG. 3 depicts a top view of through-silicon vias 302. A minimum pitch 304 between the through-silicon vias 302 is determined by the manufacturing process technology. The thickness of the silicon through which the through-silicon vias 302 traverse is a determining factor in the minimum pitch 304, making it challenging to achieve higher densities of the through-silicon vias 302.

A keep-out region 306 is configured around the through-silicon vias 302 where placement of transistors and metal connections is disallowed. The presence of the keep-out regions 306 may complicate layout of the die through which the through-silicon vias 302 traverse.

Due to their substantial impact on silicon area utilization, it is often the case that the through-silicon vias 302 are clustered on the die layout to reduce complexities on the layout of the active logic.

Back side metallization enables 3D stacking configurations that advantageously utilize higher density backside vias. Instead of a few large through-silicon vias clustered on the die, a distributed array of much smaller (in cross-section and length) backside vias may be utilized to provide similar electrical properties (such as impedance) as do fewer, clustered, large through-silicon vias, while avoiding the provisioning of keep-out regions and disruptions to the bottom die's layout that come with utilization of larger through-silicon vias.

FIG. 4 depicts an exemplary distributed placement of back side pass-through vias 402 to provide back side-to-front side power and IO connections. The back side pass-through vias 402 that provide power and IO to the front side metal layers are located in back side pass-through “dummy” cells that do not include active, functional logic circuits and that do not directly supply or route signals for active logic circuits. (The “dummy” cells utilized for power distribution may include some minimal fabricated logic such as in-silicon capacitors and possibly one or a few transistors for de-coupling the supply voltage and ground). The back side pass-through cells may be manufactured from the same geometry set (same heights and widths, for example) utilized for the active logic cells.

The dummy cells are interspersed with functional standard cells (active logic cells). The active logic cells also comprise local power and signal vias 404, also on the back side of the die, providing local power and signal distribution among the transistorized components of the functional standard cells. To mitigate the higher resistance of the individual back side pass-through vias 402 compared to larger through-silicon vias, some IO or power signals that have critical performance constraints may be routed/distributed in parallel through several of the back side pass-through vias 402, e.g., all the back side pass-through vias 402 comprised by one of the back side pass-through cells.

In one embodiment, the placement algorithm for the die may first place the back side pass-through cells in a distributed fashion across the die, and then place the active logic cells around those placements. This approach prioritizes placement of the back side pass-through cells (and hence placement and dispersed distribution of the back side pass-through vias 402) over placement of the active logic cells (and hence placement of the local power and signal vias 404). It may be desirable to align placement of the back side pass-through cells that provide power to the front side with the metal in the front side that will distribute that power to the active logic.

The distributed placement of the back side pass-through vias 402 among functional standard cells enables back side-to-front side connections with reduced disruptions to floor planning (layout) and area utilization.

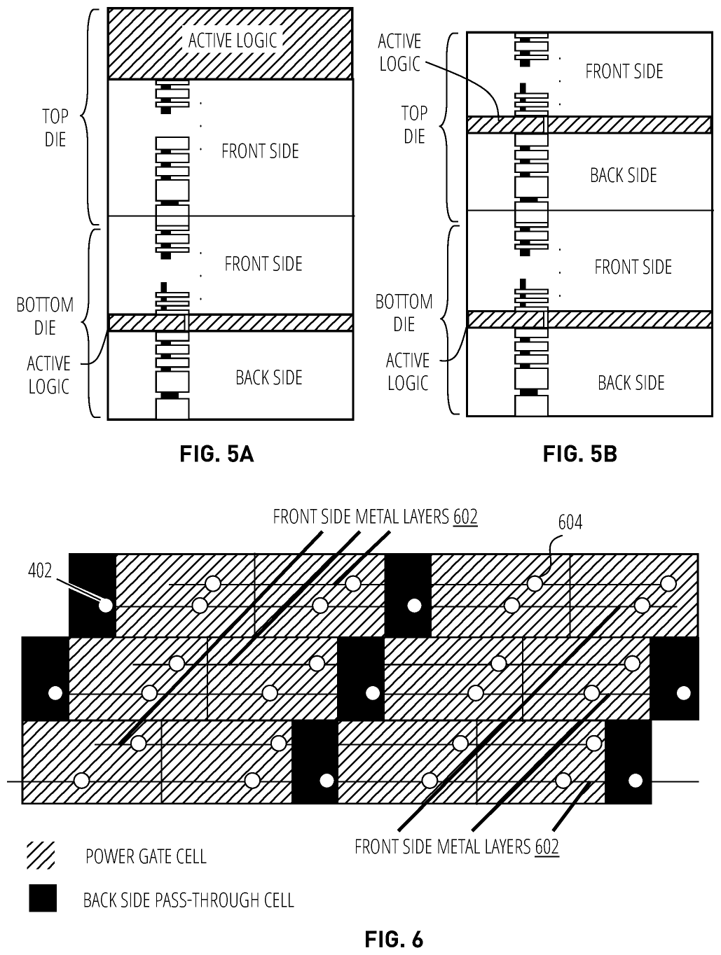

FIG. 5A and FIG. 5B depict two different implementations of 3D stacking with back side metallization. In both of these implementations, die with back side metallization are disposed at the bottom of the stack and the utilization of through-silicon vias is obviated. This enables area savings in the bottom die as well as an improved layout over configurations that utilize through-silicon vias.

In the embodiment depicted in FIG. 5A, the top die does not have back side metallization and is configured face down (front side “down”, i.e., closer than the active logic of the die to the power and IO peripheral pins). Power and IO signals are provided from the back side of the bottom die to the active logic of the top die by way of back side pass-through vias through the active logic of the bottom chip.

In the embodiment depicted in FIG. 5B, the top die does comprise back side metallization and is configured face up. Like the embodiment of FIG. 5A, power and IO signals are provided from the back side of the bottom die to the active logic of the top die by way of back side pass-through vias through the active logic of the bottom chip, however these back side signals also traverse the metal layers in the front side of top chip. Generally, in FIG. 5B, a third (or more) chip(s) may be stacked at the top of the stack in the second scenario for even denser integration.

In implementations where a cooling solution (e.g., a fan or heat sink) is disposed on the top of the stack, it may be desirable to locate the die with higher power density at or near the top of the stack. In some cases, if the stack is powered up from the bottom (e.g., from a package, substrate or interposer), it may be desirable to locate the die with stronger power grid requirements at the bottom.

Generally, the die in the stack may be manufactured using different process technologies. Consequently, their cost per unit area may vary.

An example placement of standard cells for a bottom die that utilizes back side metallization is depicted in FIG. 6. The higher density and distributed connections provided by backside vias enables finer-grained power gating and power management. For example a top die's power may be precisely managed from the bottom die using power gates and power regulating circuitry without incurring the disruptions to layout and area utilization that may arise from use of through-silicon vias.

Back side pass-through vias 402 are located in back side pass thru cells of the bottom die to provide connections to a global power supply and route the power to the front side metal layers 602 of the bottom die, from which the power is distributed to the front side of the top die using power-gated front-side vias 604 (using functional cells of the active logic of the bottom die). Power signal conditioning may also be applied at this point in the stack, for example using functional active logic cells interposed between the power gate cells and the back side pass thru cells (or vice versa). Compared to conventional configurations that use through-silicon vias, the use of the smaller, distributed back side pass-through vias 402 enables more efficient co-location of the power gating and power-conditioning logic with the power signals provided from the back side metallization, and more efficient alignment of these elements with the power distribution metal in the top side of the top die.

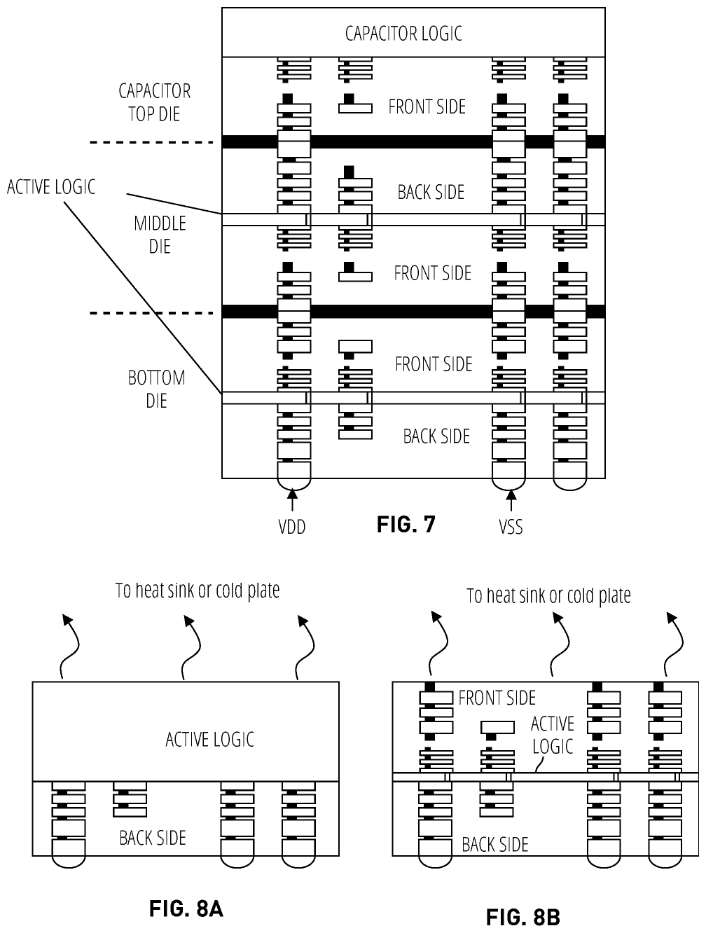

FIG. 7 depicts an embodiment in which two die utilizing back side power delivery are 3D stacked face-to-face. A third capacitor die comprising primarily capacitor logic may be stacked on top of the middle die. The capacitor chip operates an energy store to boost the power delivery network, especially to the top chip. Assuming that power is provided from the bottom, the middle die may naturally exhibit a more resistive power delivery network, and the boost provided by the capacitors facilitates with meeting current demands on the middle chip power network.

In another embodiment, the voltage domains of the middle die and the bottom die are stacked and configured such that one die operates from VDD to Vmid (˜VDD/2) and the other die operates from Vmid to VSS (e.g., circuit ground). The power distribution grids for both die are configured to provide VDD, VSS, and Vmid distribution.

This configuration may improve the energy efficiency of the two die by reducing voltage swings. The Vmid supply voltage may be regulated when the power consumption of the two die is asymmetrical. A capacitor chip may be added to facilitate regulation of the Vmid voltage level. The following table describes various configurations utilizing a capacitor chip. Embodiment 1 is depicted in FIG. 7.

| | Embodiment 1 | Embodiment 2 | Embodiment 3 |
|---|---|---|---|
| Bottom | Chip with back side | Chip with back side | Chip with back |
| die | metallization | metallization | side metallization |
| Middle | Chip with back side | Capacitor chip with | Capacitor chip |
| die | metallization | conventional TSVs | with conventional |
| | | | TSVs |
| Top | Capacitor chip | Chip with back side | Chip without back |
| die | | metallization | side metallization |

The two (non-capacitor) chips may be homogenous (i.e., the same chip) or they may be non-homogenous.

Utilizing back side metallization in 3D stacking configurations may lead to issues with heat propagation and thermal effects on the die in the stack and the system the stack is installed within. In conventional silicon process technologies, cooling is mainly performed from the side of the silicon substrate that comprises the transistors forming the main heat source. FIG. 8A depicts and example of conventional heat dissipation from a chip. For chips with back side metallization, heat may be dissipated through front or back side metal layers as depicted in FIG. 8B. The metal layers are typically separated by insulating oxide or other materials that do not conduct heat as efficiently as silicon or metal. The silicon substrate also limits lateral heat spread with the result that local hot spots may exhibit on the die.

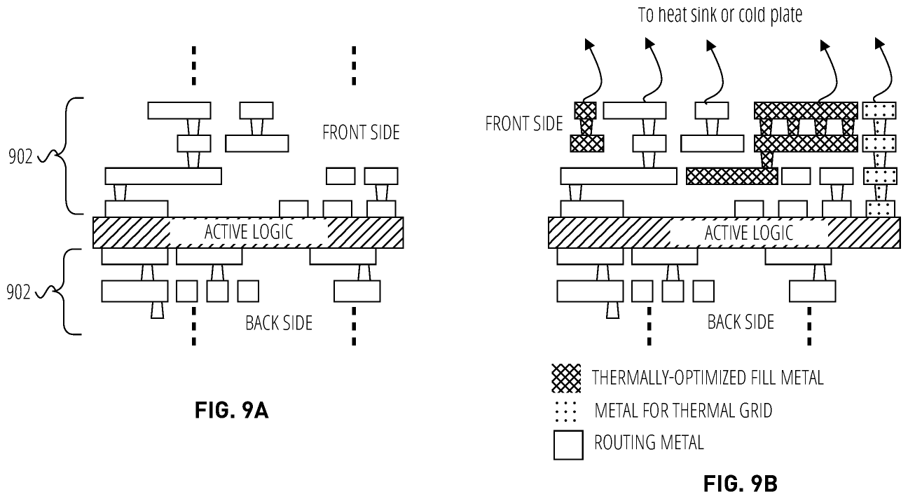

A thermal grid (continuously joined inter- and intra-layer metal tracks, similar to a power grid) and fill metal (metal tracks not utilized for signal or power routing) may be configured within the routing metal 902 layers to provide metal heat dissipation path for the die in the stack. An example of such a configuration is depicted in FIG. 9A and FIG. 9B. For die with back side metallization, this may improve heat conduction on the front side. The thermal grid and fill metal may be implemented using available metal tracks and by utilizing fill scripts that are urged to a) fill more aggressive above hot spots and b) drop more vias between fill shapes at different metal layers.

Conventionally, fill metals in different layers may not be connected with vias, as this would serve no utility. However, the disclosed mechanisms may implement thermal grids within the die by adding vias between fill metals in different layers, and/or adding additional thermal grid metal paths through the die, to improve the thermal dissipation provided therein. The thermal grid may be configured to align with hot spots (circuit areas that proportionately generate more of the total heat) on the embedded active logic layers.

In some cases the added metallization may result in an increase in parasitic capacitances due in part to interaction with the existing routing metal 902. The spacing of fill and grid metal may be adjusted to trade off between heat conductivity and impacts on power and performance optimization arising from capacitive effects. Thermal grids for top and bottom die may be vertically aligned to maximize heat transfer between them. Hot spots of one die may be aligned with a denser/thicker metal grid on the other die(s) to improve heat transfer.

Typically, there are minimum and maximum metal density manufacturing constraints for each die layer. Conventional metal fill scripts are designed to satisfy the minimum density constraints to avoid additional parasitic capacitance resulting from a denser fill pattern which can affect power and performance. To mitigate thermal effects, the metal fill scripts may be configured with more aggressive per-layer constraints, up to the maximum available for a particular layer and the process.

A higher than minimum post-fill metal density may be set to trade off between better thermal conductivity and greater parasitic loadings (which can lead to slower speeds and higher power consumption). Thus, thermal-mitigation fill patterns and densities may be optimized based on i) a level of parasitics introduced my the additional metal and its effect on power and performance, ii) improvements in thermal conductivity achieved at the higher densities, and iii) minimum and maximum density rules for the layer and process. Connecting fill metals to circuit ground may also increase heat dissipation due to the greater connectivity this provides to the heat dissipation grid. However, these ground connections may introduce parasitic effects as noted prior.

### LISTING OF DRAWING ELEMENTS

102 bottom die
104 through-silicon via
106 top die
108 active logic
110 interposer
112 active logic
114 package
116 solder terminal
118
120
202 active logic
204 front side metal layers
206 back side metal layers
208 metal layers
210 solder pin
212 solder pin
214 inter-metal layer vias
216 back side via
302 through-silicon vias
304 minimum pitch
306 keep-out region
402 back side pass-through vias
404 local power and signal vias
602 front side metal layers
604 front side via
902 routing metal
904

Various functional operations described herein may be implemented in logic that is referred to using a noun or noun phrase reflecting said operation or function. For example, an association operation may be carried out by an “associator” or “correlator”. Likewise, switching may be carried out by a “switch”, selection by a “selector”, and so on. “Logic” refers to machine memory circuits and non-transitory machine readable media comprising machine-executable instructions (software and firmware), and/or circuitry (hardware) which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory (both volatile and nonvolatile), and firmware are examples of logic. Logic specifically excludes pure signals or software per se (however does not exclude machine memories comprising software and thereby forming configurations of matter). Logic symbols in the drawings should be understood to have their ordinary interpretation in the art in terms of functionality and various structures that may be utilized for their implementation, unless otherwise indicated.

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical, such as an electronic circuit). More specifically, this formulation is used to indicate that this structure is arranged to perform the one or more tasks during operation. A structure can be said to be “configured to” perform some task even if the structure is not currently being operated. A “credit distribution circuit configured to distribute credits to a plurality of processor cores” is intended to cover, for example, an integrated circuit that has circuitry that performs this function during operation, even if the integrated circuit in question is not currently being used (e.g., a power supply is not connected to it). Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed FPGA, for example, would not be considered to be “configured to” perform some specific function, although it may be “configurable to” perform that function after programming.

Reciting in the appended claims that a structure is “configured to” perform one or more tasks is expressly intended not to invoke 35 U.S.C. § 112(f) for that claim element. Accordingly, claims in this application that do not otherwise include the “means for” [performing a function] construct should not be interpreted under 35 U.S.C § 112(f).

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

As used herein, the phrase “in response to” describes one or more factors that trigger an effect. This phrase does not foreclose the possibility that additional factors may affect or otherwise trigger the effect. That is, an effect may be solely in response to those factors, or may be in response to the specified factors as well as other, unspecified factors. Consider the phrase “perform A in response to B.” This phrase specifies that B is a factor that triggers the performance of A. This phrase does not foreclose that performing A may also be in response to some other factor, such as C. This phrase is also intended to cover an embodiment in which A is performed solely in response to B.

As used herein, the terms “first,” “second,” etc. are used as labels for nouns that they precede, and do not imply any type of ordering (e.g., spatial, temporal, logical, etc.), unless stated otherwise. For example, in a register file having eight registers, the terms “first register” and “second register” can be used to refer to any two of the eight registers, and not, for example, just logical registers 0 and 1.

When used in the claims, the term “or” is used as an inclusive or and not as an exclusive or. For example, the phrase “at least one of x, y, or z” means any one of x, y, and z, as well as any combination thereof.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

Although the terms “step” and/or “block” may be used herein to connote different elements of methods employed, the terms should not be interpreted as implying any particular order among or between various steps herein disclosed unless and except when the order of individual steps is explicitly described.

Having thus described illustrative embodiments in detail, it will be apparent that modifications and variations are possible without departing from the scope of the intended invention as claimed. The scope of inventive subject matter is not limited to the depicted embodiments but is rather set forth in the following Claims.

What is claimed is:

1. A three-dimensional integrated circuit configuration comprising:
a first die;
a second die configured with second die back side metallization; and
the second die configured to provide power from the second die back side metallization to the first die by way of second die back side pass-through vias formed in dummy cells interspersed among second die active logic cells.

2. The three-dimensional integrated circuit configuration of claim 1, wherein the first die is configured face down.

3. The three-dimensional integrated circuit configuration of claim 2, wherein the first die is configured with first die back side metallization.

4. The three-dimensional integrated circuit configuration of claim 3, further comprising a capacitor die configured face down on the first die.

5. The three-dimensional integrated circuit configuration of claim 2, wherein the first die is not configured with back side metallization.

6. The three-dimensional integrated circuit configuration of claim 1, wherein the first die is configured face up.

7. The three-dimensional integrated circuit configuration of claim 6, wherein the first die is configured with first die back side metallization.

8. The three-dimensional integrated circuit configuration of claim 1, the second die comprising multiple layers of interconnected front side fill metals.

9. The three-dimensional integrated circuit configuration of claim 1, the second die configured with power gating cells interposed between the second die back side pass-through vias and second die front side metallization.

10. The three-dimensional integrated circuit configuration of claim 1, the second die configured with power conditioning cells interposed between the second die back side pass-through vias and second die front side metallization.

11. The three-dimensional integrated circuit configuration of claim 1, wherein one or both of the first die and the second die are configured with metallization forming a thermal grid.

12. The three-dimensional integrated circuit configuration of claim 11, wherein the thermal grid comprises interconnected fill metal layers.

13. The three-dimensional integrated circuit configuration of claim 11, wherein the thermal grid is aligned with hot spots on one or both of the first die and the second die.

14. A three-dimensional integrated circuit configuration comprising:
a bottom die configured with bottom die back side metallization and bottom die front side metallization;
a top die configured with metal layers adjacent to the bottom die front side metallization; and
the bottom die configured to pass power from the bottom die back side metallization to the metal layers of the top die by way of back side pass-through vias formed in dummy cells interspersed among active logic cells of the bottom die.

15. The three-dimensional integrated circuit configuration of claim 14, wherein the bottom die front side metallization is configured adjacent to top die front side metallization.

16. The three-dimensional integrated circuit configuration of claim 15, wherein the top die is not configured with back side metallization.

17. The three-dimensional integrated circuit configuration of claim 14, wherein the bottom die front side metallization is configured adjacent to top die back side metallization.

18. A three-dimensional integrated circuit configuration comprising:
a bottom die configured with bottom die back side metallization and bottom die front side metallization;
a middle die configured with metal layers adjacent to the bottom die front side metallization;
a top die configured with metal layers adjacent to metal layers of the middle die; and
the bottom die configured to pass power from the bottom die back side metallization to the metal layers of the middle die by way of back side pass-through vias formed in dummy cells interspersed among active logic cells of the bottom die.

19. The three-dimensional integrated circuit configuration of claim 18, wherein the bottom die front side metallization is configured adjacent to middle die front side metallization.

20. The three-dimensional integrated circuit configuration of claim 19, wherein the middle die is a capacitor die.

21. The three-dimensional integrated circuit configuration of claim 20, wherein the capacitor die is configured to pass the power to top die front side metallization by way of through-silicon vias.

22. The three-dimensional integrated circuit configuration of claim 20, wherein the capacitor die is configured to pass the power to top die back side metallization by way of through-silicon vias.

23. The three-dimensional integrated circuit configuration of claim 18, wherein the bottom die front side metallization is configured adjacent to middle die back side metallization.

24. The three-dimensional integrated circuit configuration of claim 18, wherein the top die is configured with metallization forming a thermal grid.

25. The three-dimensional integrated circuit configuration of claim 24, wherein the thermal grid comprises interconnected fill metal layers.

26. The three-dimensional integrated circuit configuration of claim 24, wherein the thermal grid is aligned with hot spots on the middle die.
